(19) United States
(12) Patent Application Publication
(10) Pub. No.: US 2025/0314699 A1
(43) Pub. Date: Oct. 9, 2025

(54) DISPLAY SYSTEM, VEHICLE, AND METHOD OF DISPLAYING DEGREE OF DETERIORATION OF BATTERY

(71) Applicant: TOYOTA JIDOSHA KABUSHIKI KAISHA, Toyota-shi (JP)

(72) Inventor: Yosuke WADA, Nagakute-shi (JP)

(73) Assignee: TOYOTA JIDOSHA KABUSHIKI KAISHA, Toyota-shi (JP)

(21) Appl. No.: 19/037,288

(22) Filed: Jan. 27, 2025

(30) Foreign Application Priority Data
Apr. 9, 2024 (JP) 2024-062536

(51) Int. Cl. G01R 31/36; B60L 58/16; G01R 31/367; G01R 31/392; H02J 7/00

(52) U.S. Cl. CPC G01R 31/3648; B60L 58/16; G01R 31/367; G01R 31/392; H02J 7/0049; B60L 2250/16

(57) ABSTRACT

A display system includes an instrument panel, and an ECU controlling the instrument panel. The ECU repeatedly calculates a full charge capacity of a battery by using an amount of change in state of charge (SOC) of the battery and an amount of electricity charged into or discharged from the battery and, based on the full charge capacities calculated, determines a capacity retention ratio (degree of deterioration) to be displayed on the instrument panel. The ECU controls the instrument panel such that the capacity retention ratio determined through a smoothing process performed on the full charge capacities is displayed in an area where the rate of change of the full charge capacities is less than a predetermined value, and such that the capacity retention ratio not subjected to the smoothing process is displayed in an area where the rate of change is more than the predetermined value.

### CROSS-REFERENCE TO RELATED APPLICATION

This application claims priority to Japanese Patent Application No. 2024-062536 filed on Apr. 9, 2024, incorporated herein by reference in its entirety.

### BACKGROUND

### 1. Technical Field

The present disclosure relates to a display system, a vehicle, and a method of displaying a degree of deterioration of a battery.

### 2. Description of Related Art

In general, batteries deteriorate with usage or as time elapses. When a battery deteriorates, the full charge capacity of the battery decreases, and user convenience can be reduced. Accordingly, technologies for informing a user of a degree of deterioration of a battery have been proposed. For example, Japanese Unexamined Patent Application Publication No. 2020-58122 discloses a presentation device that can allow a user to recognize specific measures for restraining the deterioration of a battery.

### SUMMARY

When a degree of deterioration of a battery is displayed, the degree of deterioration that is calculated based on the full charge capacity of the battery can vary due to various errors. Accordingly, it can be thought that a degree of deterioration is displayed after a certain amount of processing (more specifically, a smoothing process, which will be described later) is performed. On the other hand, if a discrepancy occurs between a displayed degree of deterioration and an actual degree of deterioration, a user may be made to feel uncomfortable. It is preferable to inform the user of an accurate degree of deterioration of a battery, without causing the user to feel discomfort.

The present disclosure has been made to solve the problem as described above, and an object of the present disclosure is to inform a user of an accurate degree of deterioration of a battery, without causing the user to feel discomfort.

(1) A display system according to an aspect of the present disclosure includes: a display; and a control device that controls the display. The control device repeatedly calculates a full charge capacity of a battery by using an amount of change in state of charge (SOC) of the battery and an amount of electricity charged into or discharged from the battery. The control device determines a degree of deterioration of the battery to be displayed on the display, based on a plurality of the full charge capacities calculated. The control device controls the display in such a manner that in an area where the rate of change of the full charge capacities is less than a predetermined value, the degree of deterioration that is determined through a smoothing process performed on the full charge capacities is displayed. The control device controls the display in such a manner that in an initial area where the rate of change is more than the predetermined value, the degree of deterioration that is not subjected to the smoothing process is displayed.

According to the configuration in (1), the smoothing process is not performed in the area (an initial deterioration period, which will be described later) where the rate of change of the full charge capacities is less than the predetermined value. The smoothing process is performed in the area (a period after the initial deterioration period) where the rate of change of the full charge capacities is more than the predetermined value. By configuring the smoothing process not to be performed in the initial deterioration period, an actual degree of deterioration (for example, a capacity retention ratio) rapidly decreases in the initial deterioration period, whereby the degree of deterioration displayed on the display can be prevented from deviating from the actual degree of deterioration. Accordingly, it is possible to inform a user of an accurate degree of deterioration. On the other hand, by configuring the smoothing process to be performed in the period after the initial deterioration period, it is possible to inform a user of a degree of deterioration, without causing the user to feel discomfort. Accordingly, according to the configuration in (1), it is possible to inform a user of an accurate degree of deterioration of the battery, without causing the user to feel discomfort.

(2) In the smoothing process, the control device weights each of the full charge capacities in such a manner that a larger weight is given to a newer full charge capacity of the full charge capacities.

According to the configuration in (2), it is possible to make a newer full charge capacity more greatly reflected in the degree of deterioration subjected to the smoothing process.

(3) A vehicle according to another aspect of the present disclosure includes: the display system according to (1) or (2); and the battery. When a distance traveled by the vehicle is less than a predetermined distance, or when a period from a time of manufacture of the vehicle is less than a predetermined period of time, the control device controls the display in such a manner that a fixed value indicating that the battery has not deteriorated is displayed as the degree of deterioration.

If the degree of deterioration displayed on the display rises or falls due to errors in measurement of the degree of deterioration of the battery or the like although the distance traveled by the vehicle is less than the predetermined distance (in other words, although the vehicle is new), a user may be caused to feel discomfort or dissatisfaction. According to the configuration in (3), when the traveled distance is less than the predetermined distance (that is, in a case of a new vehicle), the degree of deterioration displayed on the display is configured to be a fixed value (for example, a capacity retention ratio of 100%) that indicates that the battery has not deteriorated. Thus, the discomfort and dissatisfaction of the user can be alleviated.

(4) A display system according to still another aspect of the present disclosure includes a display that displays a degree of deterioration of a battery determined based on time-series data on a full charge capacity of the battery. The display displays the degree of deterioration that is determined through a smoothing process performed on a plurality of the full charge capacities included in the time-series data, in an area where the rate of change of the full charge capacities is less than a predetermined value. The display displays the degree of deterioration that is not subjected to the smoothing process, in an area where the rate of change is more than the predetermined value.

(5) A method of displaying a degree of deterioration of a battery according to even another aspect of the present disclosure includes: calculating a plurality of full charge capacities of a battery by repeatedly calculating a full charge capacity of the battery by using an amount of change in state of charge (SOC) of the battery and an amount of electricity charged into or discharged from the battery; and displaying, on a display, a degree of deterioration of the battery determined based on the full charge capacities. The displaying includes displaying the degree of deterioration that is determined through a smoothing process performed on the full charge capacities, in an area where the rate of change of the full charge capacities is less than a predetermined value, and displaying the degree of deterioration that is not subjected to the smoothing process, in an initial area where the rate of change is more than the predetermined value.

According to the configuration in (4) and the method in (5), similarly to the configuration in (1), it is possible to inform a user of an accurate degree of deterioration of the battery, without causing the user to feel discomfort.

According to the present disclosure, it is possible to inform a user of an accurate degree of deterioration of a battery, without causing the user to feel discomfort.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 shows the entire configuration of a vehicle in which a display system according to an embodiment of the present disclosure is mounted;

FIG. 2 shows an example of a form of display of the capacity retention ratio of a battery on an instrument panel;

FIG. 3 is a diagram for describing an example of changes over time in capacity retention ratio of the battery;

FIG. 4 is a conceptual diagram for describing a method of displaying the battery in a comparative example;

FIG. 5 is a conceptual diagram for describing a method of displaying the battery in the present embodiment; and

FIG. 6 is a flowchart showing an example of a processing procedure for the method of displaying the capacity retention ratio of the battery in the present embodiment.

### DETAILED DESCRIPTION OF EMBODIMENTS

Hereinafter, an embodiment of the present disclosure is described in detail with reference to the drawings. Note that the same or corresponding parts are denoted by the same reference signs throughout the drawings, and a description of such parts is not repeated.

In the embodiment described below, a description is given of a configuration in which a “display system” according to the present disclosure is mounted in a vehicle, as an example. However, application of the “display system” according to the present disclosure is not limited to vehicles. The “display system” may be mounted in stationary devices, or in portable devices.

### EMBODIMENT

### System Configuration

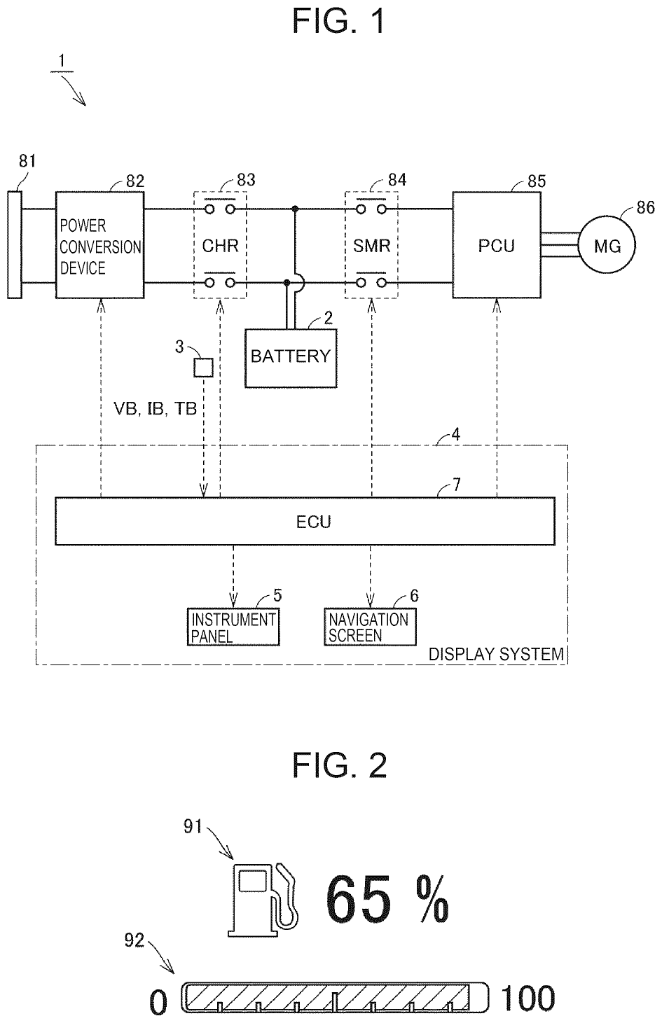

FIG. 1 shows the entire configuration of the vehicle in which the display system according to the embodiment of the present disclosure is mounted. The vehicle 1 includes a battery 2, a monitoring unit 3, and the display system 4.

The battery 2 is a direct-current power supply configured to be rechargeable and dischargeable. Typically, the battery 2 is a secondary battery, such as a lithium ion secondary battery or a nickel-metal hydride battery.

The monitoring unit 3 monitors the state of the battery 2. More specifically, the monitoring unit 3 includes a voltage sensor that detects the voltage VB of the battery 2, a current sensor that detects the currents IB input into and output from the battery 2, and a temperature sensor that detects the temperature TB of the battery 2 (none of which are depicted).

The display system 4 displays various states of the vehicle 1. The display system 4 includes an instrument panel 5, a navigation screen 6, and an electronic control unit (ECU) 7.

The instrument panel 5 is a dashboard in which meters and the like are installed. The instrument panel 5 notifies various states of the vehicle 1 to a user in accordance with a control command from the ECU 7. The instrument panel 5 is an example of a “display” according to the present disclosure.

The navigation screen 6 is a display provided in a navigation system. The navigation screen 6 notifies various states of the vehicle 1 to the user in accordance with a control command from the ECU 7. The navigation screen 6 is another example of the “display” according to the present disclosure.

The ECU 7 includes a processor, such as a central processing unit (CPU) or a micro processing unit (MPU), memory including a random access memory (RAM) and a read only memory (ROM), and input-output ports (none of which are depicted). The ECU 7 outputs a control signal, based on inputs of signals from the individual sensors and a map and a program stored in the memory, and controls each equipment in such a manner that the vehicle 1 falls in a desired state. Major controls that are performed by the ECU 7 in the present embodiment include a process of causing the instrument panel 5 to display an indicator indicating a degree of deterioration of the battery 2. In the present embodiment, a capacity retention ratio of the battery 2 is displayed on the instrument panel 5. The capacity retention ratio of the battery 2 corresponds to a “degree of deterioration” according to the present disclosure. The “degree of deterioration” may be the full charge capacity of the battery 2 itself, or a value converted from the full charge capacity of the battery 2 (for example, a distance that the vehicle I can travel when the battery 2 is fully charged). The “degree of deterioration” may be displayed on another display, such as the navigation screen 6.

The vehicle 1 is configured to be able to be plugged in and charged. The vehicle 1 further includes an inlet 81 that is connected to an external charging facility (not depicted), a power conversion device 82, a charge relay (CHR) 83, a system main relay (SMR) 84, a power control unit (PCU) 85, and a motor generator 86.

### Display of Degree of Deterioration

FIG. 2 shows an example of a form of display of the capacity retention ratio of the battery 2 on the instrument panel 5. The instrument panel 5 is configured to display an icon 91 that indicates a state of charge (SOC) of the battery 2, and an icon 92 that indicates a capacity retention ratio of the battery 2. In the example shown in FIG. 2, the icon 92 that indicates a capacity retention ratio of the battery 2 is configured to perform meter display. The meter decreases as deterioration of the battery 2 progresses. The form of display of the icon 92 is not particularly limited, although other forms of display are not depicted. For example, the icon 92 may be displayed by using a segment display technique, or may be displayed as a numerical value (as a percentage).

### Decrease in Capacity Retention Ratio

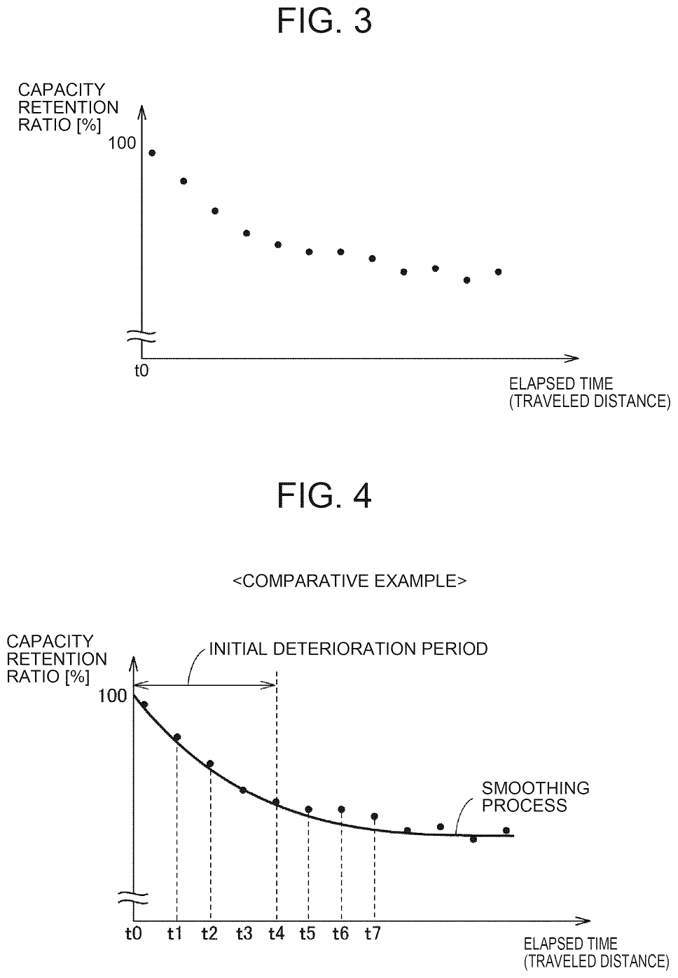

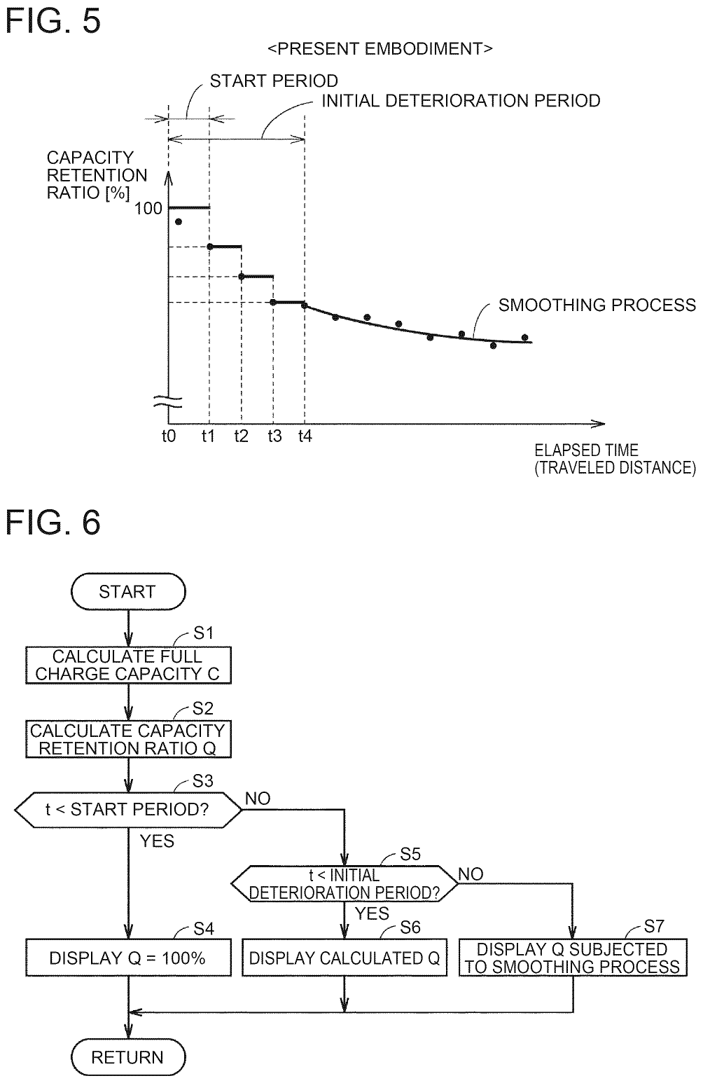

FIG. 3 is a diagram for describing an example of changes over time in capacity retention ratio of the battery 2. In FIG. 3, and FIGS. 4 and 5, which will be described later, a horizontal axis represents elapsed time since time to of manufacture of the vehicle 1 (or the battery 2). The capacity retention ratio of a battery is generally expressed as the ratio of a full charge capacity of the battery at a current point of time to a full charge capacity of the battery in an initial state (at a time of manufacture of a vehicle). The horizontal axis may represent the distance traveled by the vehicle 1 instead. A vertical axis represents the capacity retention ratio Q of the battery 2. The vertical axis may represent the full charge capacity of the battery (or the distance that the vehicle I can travel) instead.

In general, the capacity retention ratio of a battery basically monotonically decreases as time elapses, although some rises and falls can occur due to variations in measurement and the like. Here, it has been known that initial deterioration occurs in batteries. Accordingly, as shown in FIG. 3, the capacity retention ratio of a battery sharply decreases in an initial deterioration period (a first few months to a few years after the vehicle 1 (battery 2) is manufactured), and thereafter the decrease in capacity retention ratio slows.

FIG. 4 is a conceptual diagram for describing a method of displaying the battery 2 in a comparative example. As described above, the capacity retention ratio of a battery can rise and fall due to variations in measurement and the like. Accordingly, it can be considered that a smoothing process is performed on a plurality of capacity retention ratios and a capacity retention ratio after the smoothing process is displayed on the instrument panel 5. By performing the smoothing process, it is possible to restrain the capacity retention ratio from sharply decreasing, or increasing (recovering, which is not supposed to happen in a normal condition), and to allow a user to know the capacity retention ratio without feeling discomfort.

Note that the smoothing process is typically a weighted averaging process. In other words, in the weighted averaging process, first, values (numerical values× weights), each obtained by multiplying each numerical value (a capacity retention ratio in the present embodiment) by a weight corresponding to the numerical value, are added up. A value obtained by the addition is divided by the sum of the weights.

In the smoothing process, it is preferable to perform the weighting of each of the capacity retention ratios in such a manner that a larger weight is given to a newer capacity retention ratio of the capacity retention ratios (full charge capacities). By making a weight to a newer capacity retention ratio larger than a weight to an older capacity retention ratio, it is possible to make the newer capacity retention ratio more greatly reflected in the capacity retention ratio subjected to the smoothing process.

In the example shown in FIG. 4, a period from time to to time t4 is the initial deterioration period (period during which initial deterioration is occurring) and corresponds to an “initial area where the rate of change of the full charge capacities is more than the predetermined value” in the present disclosure. A period after time t4, that is, after the above period ends, is a period after the initial deterioration period and corresponds to an “area where the rate of change of the full charge capacities is less than a predetermined value” in the present disclosure.

In the comparative example, the smoothing process is performed over all the periods. In general, when the smoothing process is performed, changes in capacity retention ratio become slow, compared to when the smoothing process is not performed. As a result, a discrepancy can occur between a capacity retention ratio obtained through the smoothing process (that is, a capacity retention ratio displayed on the instrument panel 5) and an actual capacity retention ratio. For example, during the initial period, while the actual capacity retention ratio rapidly decreases, the capacity retention ratio subjected to the smoothing process does not decrease so rapidly. Accordingly, the capacity retention ratio displayed on the instrument panel 5 may be higher than the actual capacity retention ratio. Conversely, after the initial period elapses, since the capacity retention ratio subjected to the smoothing process is low with an effect of the initial deterioration, the capacity retention ratio displayed on the instrument panel 5 may be lower than the actual capacity retention ratio.

Accordingly, in the present embodiment, a change between performing the smoothing process and not performing the smoothing process is made between the initial deterioration period (period during which initial deterioration is occurring) and the period thereafter. The smoothing process is not performed in the initial deterioration period, and the smoothing process is performed after the initial deterioration period.

FIG. 5 is a conceptual diagram for describing a method of displaying the battery 2 in the present embodiment. In the illustrated example, in a start period (a period from t0 to t1) that is the most initial period after the vehicle 1 is manufactured, the capacity retention ratio is displayed as 100% on the instrument panel 5. The period to t1 may be a period until a predetermined short time (for example, one month) elapses from the time of manufacture of the vehicle 1. The period to t1 may be a period until the distance traveled by the vehicle 1 reaches a predetermined short distance (for example, 1000 km).

When the capacity retention ratio displayed on the instrument panel 5 exceeds 100% due to an error in measurement of the capacity retention ratio, the user may feel uncomfortable. Moreover, when the capacity retention ratio displayed on the instrument panel 5 during the start period is less than 100%, the user can feel the dissatisfaction that “the capacity retention ratio immediately drops despite the new car.” By fixing the capacity retention ratio displayed on the instrument panel 5 during the start period at 100%, such discomfort and dissatisfaction can be alleviated. Note that a capacity retention ratio of 100% corresponds to a “fixed value indicating that the battery has not deteriorated” in the present disclosure.

In the initial deterioration period excluding the start period (a period from t1 to t4), the smoothing process is not performed, and an actual capacity retention ratio is displayed as it is on the instrument panel 5. Thus, the errors due to the smoothing process as described above can be restrained from occurring.

The following period after the initial deterioration period (a period after t4), the smoothing process is performed, and a capacity retention ratio obtained through the smoothing process is displayed on the instrument panel 5. Thus, variations in capacity retention ratio due to errors in measurement of the capacity retention ratio can be reduced.

### Processing Flow

FIG. 6 is a flowchart showing an example of a processing procedure for the method of displaying the capacity retention ratio of the battery 2 in the present embodiment. Processes shown in the flowchart are invoked from an undepicted main routine and executed each time a predetermined condition is fulfilled (for example, at each predetermined interval). In other words, the processes are executed repeatedly. Each step is implemented through software processing by the ECU 7, but also may be implemented by hardware (electric circuitry) disposed in the ECU 7. Hereinafter, each step is abbreviated as S.

In S1, the ECU 7 calculates a full charge capacity C of the battery 2. More specifically, the ECU 7 estimates a SOC of the battery 2 before and after the battery 2 is charged or discharged (for example, before plugging-in and charging of the vehicle 1 is started and after the plugging-in and charging is finished). Moreover, the ECU 7 acquires an amount of electricity ΔAh charged into or discharged from the battery 2 between the two SOC estimations by cumulative addition of currents. In such a case, the ECU 7 can calculate the full charge capacity C of the battery 2 in accordance with an expression (1) below, by using S1, S2 that are results of the two SOC estimation processes and the amount of electricity ΔAh charged or discharged.

$$C = Δ Ah / ( S 1 - S 2 ) \times 100 \qquad ( 1 )$$

In S2, the ECU 7 calculates a capacity retention ratio Q from the full charge capacity C calculated in S1. The capacity retention ratio Q is the ratio of the full charge capacity C at the current point of time to a reference capacity Cref, and can be calculated in accordance with an expression (2) below. The reference capacity Cref is typically a capacity at a time of manufacture of a battery and is predetermined. The reference capacity Cref is stored beforehand in the memory of the ECU 7.

$$Q = C / Cref \times 100 \qquad ( 2 )$$

In S3, the ECU 7 determines whether or not an elapsed period t since the time of manufacture of the vehicle 1 is less than the length of the start period (for example, one month). Instead, the ECU 7 may determine whether or not a distance traveled by the vehicle 1 is less than a short distance (for example, 1000 km). When the elapsed period t is less than the length of the start period (YES in S3), the ECU 7 controls the instrument panel 5 in such a manner that capacity retention ratio Q=100% is displayed on the instrument panel 5 in a fixed manner, regardless of the capacity retention ratio calculated in S2 (S4).

When the elapsed period t is equal to or more than the length of the start period (NO in S3), the ECU 7 determines whether or not the elapsed period t is less than the length of the initial deterioration period (for example, in the range of a few months to a few years) (S5). Instead, the ECU 7 may determine whether or not the distance traveled by the vehicle 1 is less than a middle distance (for example, in the range of a few thousand km to 10,000 km). When the elapsed period t is less than the length of the initial deterioration period (YES in S5), the ECU 7 controls the instrument panel 5 in such a manner that the capacity retention ratio Q calculated in S2 is displayed as it is on the instrument panel 5 (S6).

When the elapsed period t is equal to or more than the length of the initial deterioration period (NO in S5), the ECU 7 controls the instrument panel 5 in such a manner that a capacity retention ratio Q subjected to the smoothing process after the initial deterioration period elapses is displayed on the instrument panel 5 (S7).

After the process in any of S4, S6, S7 is finished, the ECU 7 returns the processing to the main routine. Thus, a series of the processes ends.

As described above, in the present embodiment, the smoothing process is not performed in the initial deterioration period, and the smoothing process is performed in the period after the initial deterioration period. By configuring the smoothing process not to be performed in the initial deterioration period, the actual capacity retention ratio rapidly decreases in the initial deterioration period. Thus, a capacity retention ratio displayed on the instrument panel 5 can be prevented from being higher than the actual capacity retention ratio. Accordingly, it is possible to inform a user of an accurate capacity retention ratio. On the other hand, by performing the smoothing process in the period after the initial deterioration period, it is possible to inform the user of a capacity retention ratio, without causing the user to feel discomfort. Accordingly, according to the present embodiment, it is possible to inform a user of an accurate capacity retention ratio of the battery 2, without causing the user to feel discomfort.

The present embodiment disclosed herein should be construed as illustrative, not as restrictive, in all respects. The scope of the present disclosure is indicated not by the description of the embodiment but by claims, and is intended to include equivalent meanings to the claims and all changes made in the scope of the claims.

What is claimed is:

1. A display system comprising:
a display; and
a control device that controls the display,
wherein the control device
repeatedly calculates a full charge capacity of a battery by using an amount of change in state of charge (SOC) of the battery and an amount of electricity charged into or discharged from the battery and, based on a plurality of the full charge capacities calculated, determines a degree of deterioration of the battery to be displayed on the display,
controls the display in such a manner that in an area where a rate of change of the full charge capacities is less than a predetermined value, the degree of deterioration that is determined through a smoothing process performed on the full charge capacities is displayed, and
controls the display in such a manner that in an initial area where the rate of change is more than the predetermined value, the degree of deterioration that is not subjected to the smoothing process is displayed.

2. The display system according to claim 1, wherein in the smoothing process, the control device weights each of the full charge capacities in such a manner that a larger weight is given to a newer full charge capacity of the full charge capacities.

3. A vehicle comprising:
the display system according to claim 1; and
the battery,
wherein when a distance traveled by the vehicle is less than a predetermined distance, or when a period from a time of manufacture of the vehicle is less than a predetermined period of time, the control device controls the display in such a manner that a fixed value indicating that the battery has not deteriorated is displayed as the degree of deterioration.

4. A display system comprising a display that displays a degree of deterioration of a battery determined based on time-series data on a full charge capacity of the battery,
wherein the display
displays the degree of deterioration that is determined through a smoothing process performed on a plurality of the full charge capacities included in the time-series data, in an area where a rate of change of the full charge capacities is less than a predetermined value, and
displays the degree of deterioration that is not subjected to the smoothing process, in an area where the rate of change is more than the predetermined value.

5. A method of displaying a degree of deterioration of a battery, comprising:
calculating a plurality of full charge capacities of a battery by repeatedly calculating a full charge capacity of the battery by using an amount of change in state of charge (SOC) of the battery and an amount of electricity charged into or discharged from the battery; and
displaying, on a display, a degree of deterioration of the battery determined based on the full charge capacities,
wherein the displaying includes displaying the degree of deterioration that is determined through a smoothing process performed on the full charge capacities, in an area where a rate of change of the full charge capacities is less than a predetermined value, and displaying the degree of deterioration that is not subjected to the smoothing process, in an initial area where the rate of change is more than the predetermined value.
